(19) United States
(12) Patent Application Publication
(10) Pub. No.: US 2025/0374467 A1
(43) Pub. Date: Dec. 4, 2025

(54) MOUNTING ASSEMBLIES FOR REMOTE RADIO UNITS

(71) Applicant: Outdoor Wireless Networks LLC, Richardson, TX (US)

(72) Inventors: Bin Ai, Suzhou (CN); Charles J. Mann, Omaha, NE (US); Yuwei Zhao, Suzhou (CN)

(21) Appl. No.: 19/202,057

(22) Filed: May 8, 2025

(30) Foreign Application Priority Data
May 28, 2024 (CN) 202410674613.7
Aug. 12, 2024 (CN) 202411097057.8

(51) Int. Cl. H05K 7/14; F16M 13/02

(52) U.S. Cl. CPC H05K 7/1401; F16M 13/022

(57) ABSTRACT

The present application is directed to a mounting assembly for remote radio units. The mounting assembly includes a first clamping assembly and a second clamping assembly. Each clamping assembly includes front and rear clamp members held together by two threaded bolts that are inserted through aligned holes to secure the respective clamping assembly to a mounting structure. The mounting assembly further includes a first mounting panel and a second mounting panel. An end of each mounting panel secured to one of the clamp members for each clamping assembly such that the mounting panels extend outwardly from the clamping assemblies and parallel to each other. The first and second mounting panels each include a section configured to have a remote radio unit mounted thereon in a back-to-back orientation.

### RELATED APPLICATION(S)

The present application claims priority to and the benefit of Chinese Patent Application for Invention No. 202410674613.7, filed May 28, 2024, and Chinese Patent Application for Invention No. 202411097057.8, filed Aug. 12, 2024, the disclosures of which hereby are incorporated by reference herein in full.

### FIELD

The present invention relates to telecommunications equipment, and more particular to, the mounting of remote radio units.

### BACKGROUND

With increased demand for more wireless communication, the number of radio and antenna units that a tower traditionally supports has increased and is expected to continue to increase. New towers will need to be designed to support greater numbers of antenna and radio units, while existing towers are retrofitted to support more units, and effort is made to fully utilize space available on the towers.

Currently, as shown in FIG. 1 and FIGS. 2A-2B, a mounting assembly 10 may be used to mount two remote radio units (RRUs) 50 on a single mounting location. As shown in FIG. 1 and FIGS. 2A-2B, the mounting assembly 10 may include clamping members 20 and mounting panels 30 configured to have an RRU 50 mounted thereon. In some instances, additional support members 40 may be secured to the mounting panels 30 and configured to have an RRU 50 mounted thereon. Further exemplary mounting assemblies are described in U.S. Pat. Nos. 10,797,380 and 11,527,815, the disclosures of which are hereby incorporated by reference in their entireties.

While these mounting assemblies offer some advantages, the assemblies have a large number of parts which result in higher manufacturing and installation costs. In addition, because these mounting assemblies have multiple metal-to-metal contact points and fasteners used, there is a relatively high risk of passive intermodulation (PIM). Thus, there may be a desire for an alternative mounting assembly having a simpler design with a lower risk of PIM, as well as, lower associated costs.

### SUMMARY

A first aspect of the present invention is directed to a mounting assembly for remote radio units. The mounting assembly includes a first clamping assembly and a second clamping assembly. Each clamping assembly includes front and rear clamp members held together by two threaded bolts that are inserted through aligned holes to secure the respective clamping assembly to a mounting structure. The mounting assembly further includes a first mounting panel and a second mounting panel. An end of each mounting panel secured to one of the clamp members for each clamping assembly such that the mounting panels extend outwardly from the clamping assemblies and parallel to each other. The first and second mounting panels each include a section configured to have a remote radio unit mounted thereon in a back-to-back orientation.

Another aspect of the present invention is directed to a remote radio unit mounting assembly. The remote radio unit mounting assembly includes a first remote radio unit, a second remote radio unit and a mounting assembly. The mounting assembly includes a first clamping assembly and a second clamping assembly. Each clamping assembly includes front and rear clamp members held together by two threaded bolts that are inserted through aligned holes. The mounting assembly further includes a first mounting panel and a second mounting panel. An end of each mounting panel secured to one of the clamp members for each clamping assembly such that the mounting panels extend outwardly from the clamping assemblies and parallel to each other. The first remote radio unit is secured to the first mounting panel and the second remote radio unit is secured to the second mounting panel such that the first and second remote radio units are positioned in a back-to-back orientation, and the front and rear clamp members secure the respective clamping assemblies to a mounting structure.

Another aspect of the present invention is directed to a mounting assembly for remote radio units. The mounting assembly includes a first clamping assembly and a second clamping assembly. Each clamping assembly includes front and rear clamp members held together by two threaded bolts that are inserted through aligned holes to secure the respective clamping assembly to a mounting structure. The mounting assembly further includes a first mounting panel and a second mounting panel. An end of each mounting panel secured to one of the clamp members for each clamping assembly such that the mounting panels extend outwardly from the clamping assemblies and parallel to each other. Each mounting panel includes a mounting section and an extension section. The mounting section has a plurality of apertures positioned such that the mounting assembly can accommodate mounting locations for a variety of different types and/or sizes of remote radio units. The extension section configured to be secured to the clamp assemblies and position the remote radio units a sufficient distance from the mounting structure. Each mounting panel further includes one or more stabilizing members. Corresponding stabilizing members from each mounting panel are configured to align with each other to receive a fastener to couple the two mounting panels together, and the first and second mounting panels are configured to have a respective remote radio unit mounted thereon in a back-to-back orientation.

Another aspect of the present invention is directed to a mounting kit for remote radio units. The mounting kit includes a mounting assembly including a mounting bracket and a clamp member. The mounting bracket and clamp member are held together by two threaded bolts that are inserted through aligned holes to secure the mounting assembly to a mounting structure. The mounting kit further includes a first pair of mounting panels secured to an end of the mounting bracket and a second pair of mounting panels secured to an opposing end of the mounting bracket. The first pair of mounting panels extends outwardly from the mounting bracket and parallel to each other and the second pair of mounting panels extends outwardly from the mounting bracket and parallel to each other. Each mounting panel comprises a section configured to have a remote radio unit mounted thereon in a back-to-back orientation.

It is noted that aspects of the invention described with respect to one embodiment, may be incorporated in a different embodiment although not specifically described relative thereto. That is, all embodiments and/or features of any embodiment can be combined in any way and/or combination. Applicant reserves the right to change any originally filed claim and/or file any new claim, accordingly, including the right to be able to amend any originally filed claim to depend from and/or incorporate any feature of any other claim or claims although not originally claimed in that manner. These and other objects and/or aspects of the present invention are explained in detail in the specification set forth below. Further features, advantages and details of the present invention will be appreciated by those of ordinary skill in the art from a reading of the figures and the detailed description of the preferred embodiments that follow, such description being merely illustrative of the present invention.

### BRIEF DESCRIPTION OF THE DRAWINGS

FIG. 1 shows a currently available mounting assembly for remote radio units.

FIGS. 2A-2B illustrate the mounting assembly shown in FIG. 1 with remote radio units mounted back-to-back thereon.

FIG. 3A is a top perspective view of a mounting assembly according to embodiments of the present invention.

FIG. 3B is a side view of the mounting assembly shown in FIG. 3A.

FIG. 3C is a front view of the mounting assembly shown in FIG. 3A.

FIG. 3D is a top view of the mounting assembly shown in FIG. 3A.

FIG. 3E is an enlarged side view of an exemplary fastener that may be used to secure together components of the mounting assembly shown in FIG. 3A.

FIG. 4A is an exploded top perspective view of the mounting panels for the mounting assembly shown in FIGS. 3A-3D according to embodiments of the present invention.

FIG. 4B is a top perspective view of one of the mounting panels shown in FIG. 4A according to embodiments of the present invention.

FIG. 4C is a side view of the mounting panel shown in FIG. 4B.

FIG. 5 is a top view of a cut piece of sheet metal prior to bending to form the mounting panel shown in FIGS. 4B-4C according to embodiments of the present invention.

FIG. 6A is a top perspective view illustrating two mounting panels stacked together according to embodiments of the present invention.

FIG. 6B is an end view of the stacked mounting panels shown in FIG. 6A.

FIG. 6C is a top view of the stacked mounting panels shown in FIGS. 6A-6B.

FIG. 7A is a perspective view illustrating the mounting assembly shown in FIGS. 3A-3D secured to a mounting structure and having two remote radio units secured to the mounting assembly in a back-to-back orientation according to embodiments of the present invention.

FIG. 7B is a front view of the mounting assembly shown in FIG. 7A.

FIG. 7C is a top view of the mounting assembly shown in FIGS. 7A-7B.

FIGS. 8A-8B are top perspective and front perspective views of an alternative mounting assembly according to embodiments of the present invention.

FIGS. 9A-9B are top perspective and front perspective views of another alternative mounting assembly according to embodiments of the present invention.

FIGS. 10A-10B are top perspective and front perspective views of another alternative mounting assembly according to embodiments of the present invention.

FIGS. 11A-11B are top perspective and side perspective views of another alternative mounting assembly according to embodiments of the present invention.

FIG. 12A shows a size comparison of the cut pieces of sheet metal prior to bending to form the mounting panels shown in FIGS. 10A-10B and FIGS. 11A-11B.

FIG. 12B shows a size comparison of the mounting panels formed from the sheet metal shown in FIG. 12A.

FIGS. 13A-13B are top perspective and top views of another alternative mounting assembly according to embodiments of the present invention.

FIGS. 14A-14B are top perspective and top views of another alternative mounting assembly according to embodiments of the present invention.

FIG. 15A is a front perspective view of a remote radio unit mounting kit according to embodiments of the present invention.

FIG. 15B is a top view of the remote radio unit mounting kit of FIG. 15A.

FIG. 16A is a front perspective view of the mounting bracket and clamp member for the remote radio unit mounting kit of FIGS. 15A-15B according to embodiments of the present invention.

FIG. 16B is a top view of the mounting bracket and clamp member of FIG. 16A.

FIG. 16C is an exploded view of the mounting bracket shown in FIGS. 16A-16B according to embodiments of the present invention.

FIG. 16D is a front perspective view of the mounting bracket of FIG. 16C.

FIG. 16E is a rear perspective view of the mounting bracket of FIG. 16C.

FIG. 17A is a rear perspective view of a mounting assembly utilizing the mounting kit shown in FIGS. 15A-15B according to embodiments of the present invention.

FIG. 17B is a top view of the mounting assembly of FIG. 17A.

FIG. 18A is a front perspective view of an alternative configuration of the remote radio unit mounting kit (having six remote radio units mounted thereon) according to embodiments of the present invention.

FIG. 18B is a top view of the alternative configuration of the remote radio unit mounting kit shown in FIG. 18A.

FIG. 19A is a top perspective view of a mounting assembly utilizing the alternative configuration of the remote radio unit mounting kit shown in FIGS. 18A-18B according to embodiments of the present invention.

FIG. 19B is a top view of the mounting assembly shown in FIG. 19A.

FIGS. 20A-20B illustrate the capability of the mounting kit to meet carrier spacing requirements when used on a monopole platform assembly according to embodiments of the present invention.

FIGS. 21A-21B illustrate the capability of the mounting kit to meet carrier spacing requirements when used on a sector frame assembly according to embodiments of the present invention.

FIG. 22A is a front perspective view of an alternative configuration for a remote radio unit mounting kit according to embodiments of the present invention.

FIG. 22B is a top view of the remote radio unit mounting kit shown in FIG. 22A.

FIG. 23A is a is a front perspective view of the mounting bracket and clamp member for the remote radio unit mounting kit of FIGS. 22A-22B according to embodiments of the present invention.

FIG. 23B is a top view of the mounting bracket and clamp member of FIG. 22A.

FIG. 24A is a front perspective view of the mounting bracket shown in FIGS. 23A-23B according to embodiments of the present invention.

FIG. 24B is a rear perspective view of the mounting bracket of FIG. 24A.

FIG. 24C illustrates how the mounting bracket of FIGS. 24A-24B may be formed from a single piece of steel according to embodiments of the present invention.

FIG. 25A is a top perspective view of a mounting assembly utilizing the alternative configuration of the remote radio unit mounting kit shown in FIGS. 22A-22B according to embodiments of the present invention.

FIG. 25B is a top view of the mounting assembly shown in FIG. 25A.

FIG. 26 is a side-by-side comparison of the remote radio unit mounting kit shown in FIGS. 18A-18B and the remote radio unit mounting kit shown FIGS. 25A-25B.

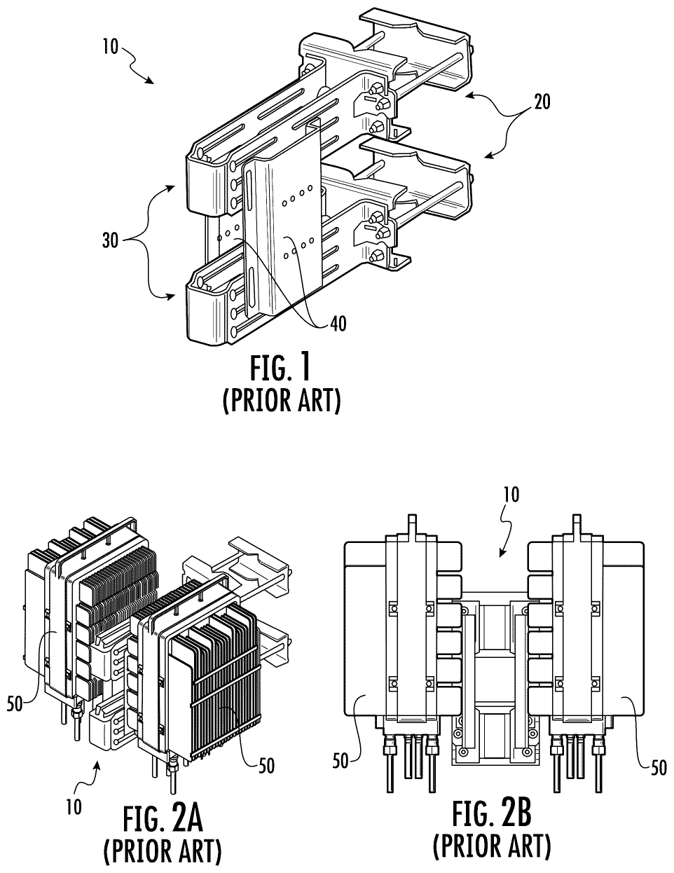

### DETAILED DESCRIPTION

The present invention now is described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

In the figures, certain layers, components, or features may be exaggerated for clarity, and broken lines illustrate optional features or operations unless specified otherwise. This invention may, however, be embodied in many different forms and should not be construed as limited to the embodiments set forth herein; rather, these embodiments are provided so that this disclosure will be thorough and complete, and will fully convey the scope of the invention to those skilled in the art.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer, or section. Thus, a first element, component, region, layer, or section discussed below could be termed a second element, component, region, layer or section without departing from the teachings of the present invention. The sequence of operations (or steps) is not limited to the order presented in the claims or figures unless specifically indicated otherwise.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “lateral”, “left”, “right” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. The device may be otherwise oriented (rotated 90 degrees or at other orientations) and the descriptors of relative spatial relationships used herein interpreted accordingly.

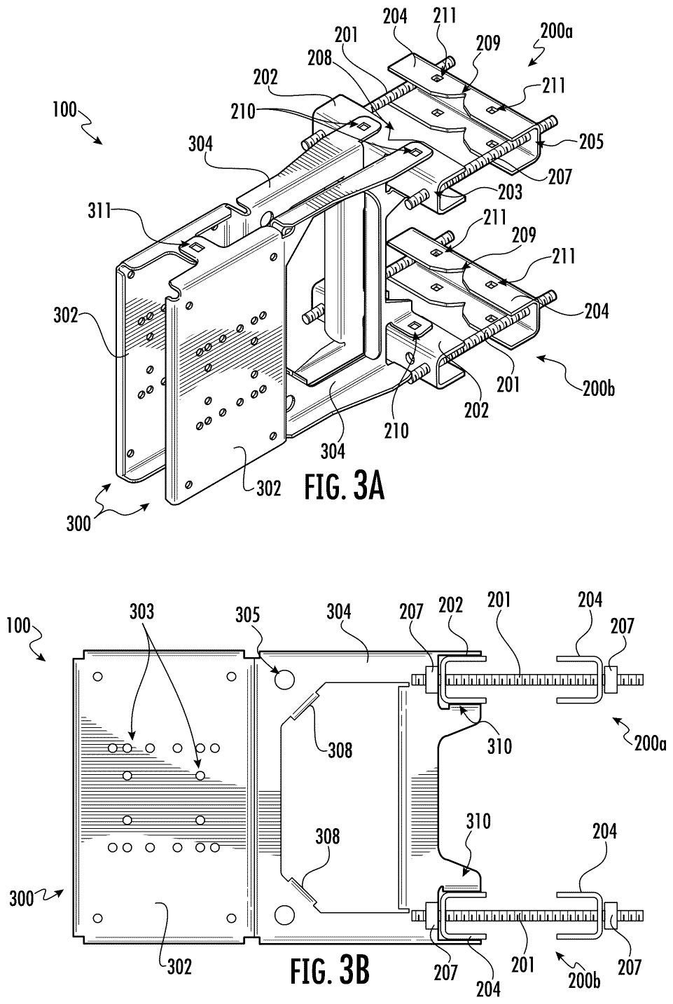

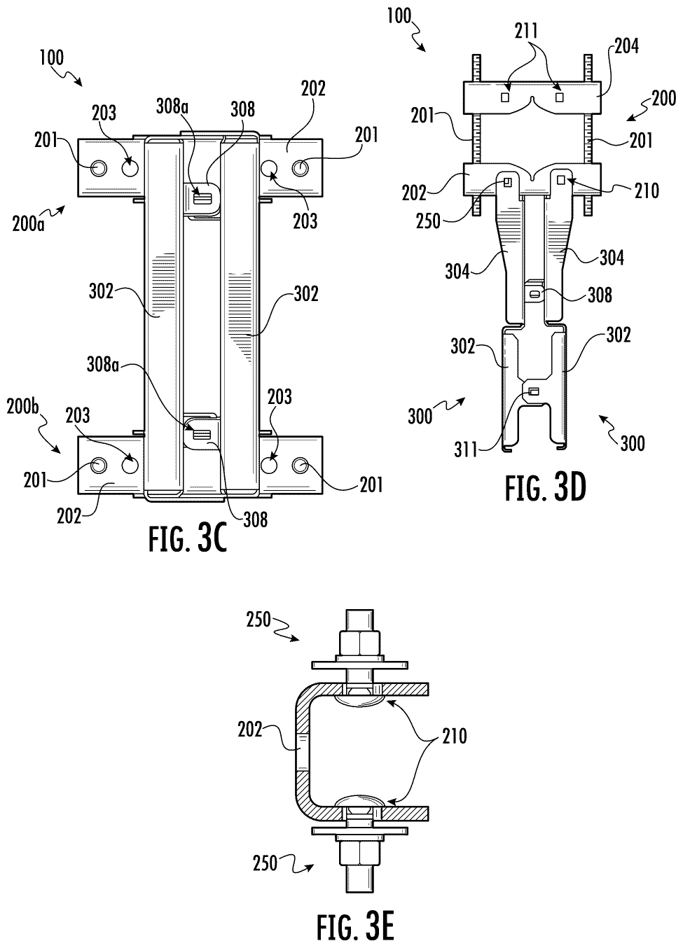

Embodiments of the present invention are directed to mounting of remote radio units (RRUs). The present invention provides a mounting assembly that allows for back-to-back mounting of remote radio units on a mounting structure. The mounting assembly provides a simpler design with a lower risk of PIM, as well as, lower associated costs. Embodiments of the present invention will now be described in further detail below with reference to FIG. 3A through FIG. 26.

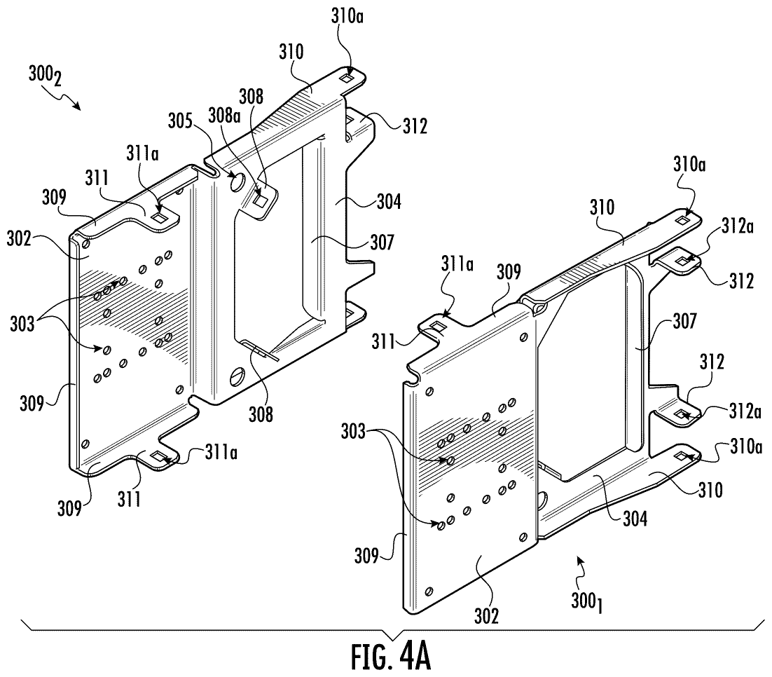

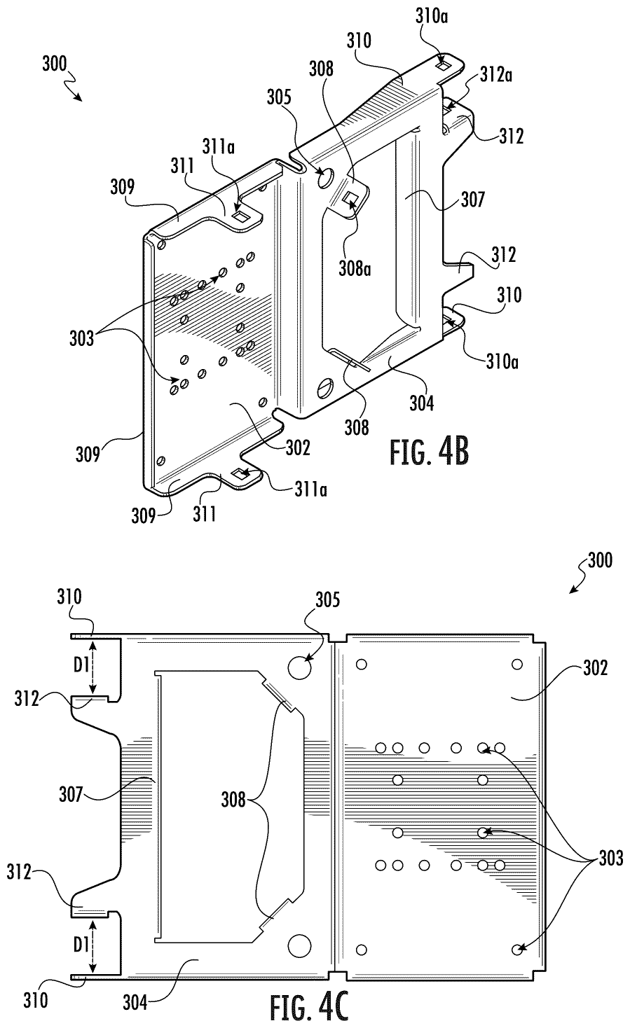

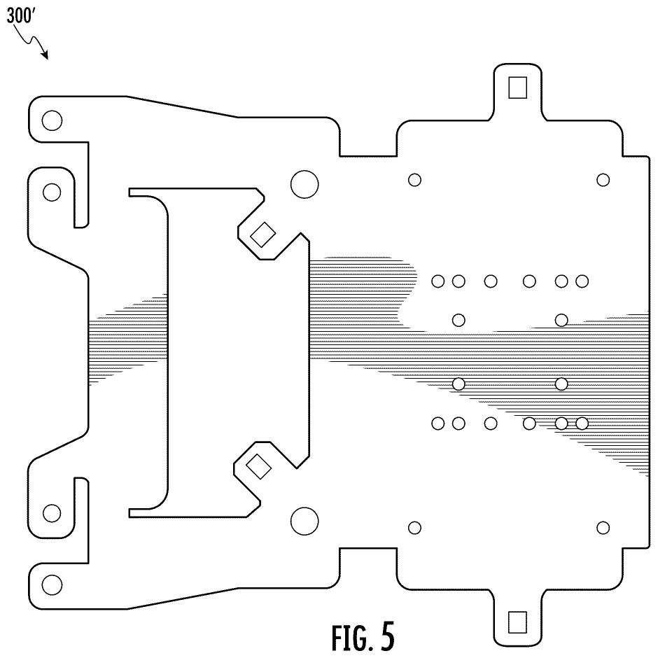

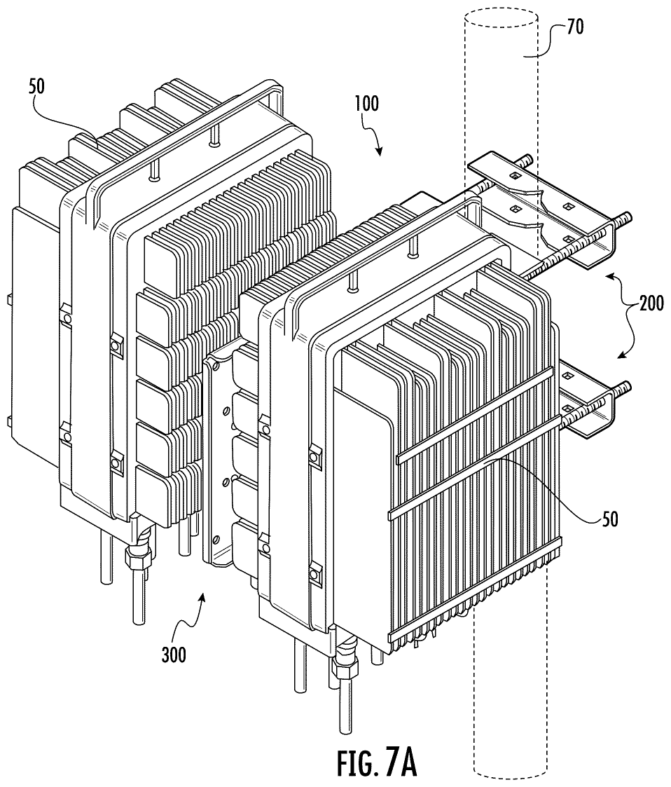

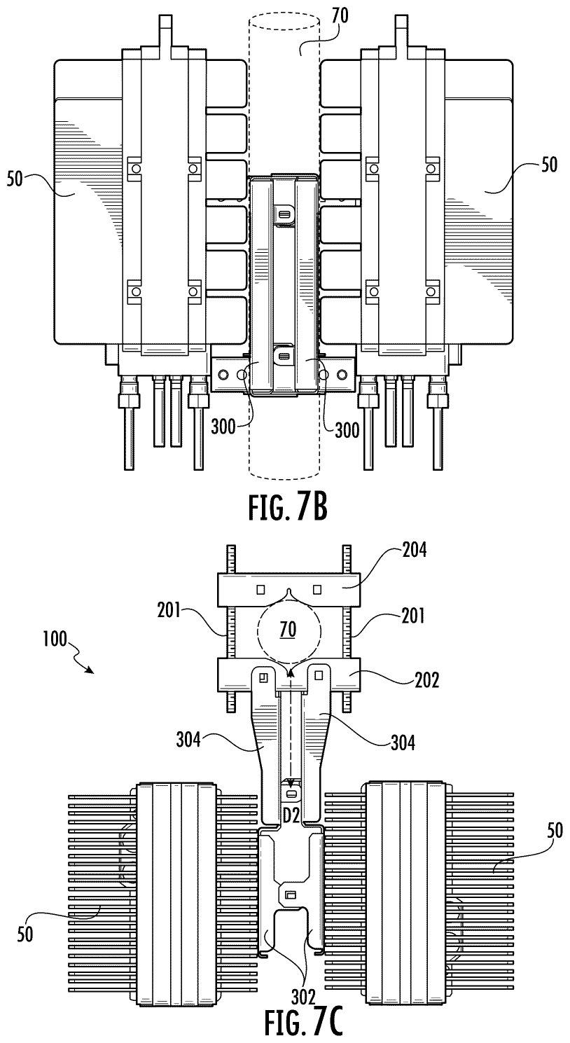

Referring to FIGS. 3A-3E and FIGS. 4A-4C, a mounting assembly 100 according to embodiments of the present invention is illustrated. The mounting assembly 100 is configured to mount two or more remote radio units 50 back-to-back on a mounting structure 70 (see, e.g., FIGS. 7A-7C). As shown in FIGS. 3A-3D, in some embodiments, the mounting assembly 100 comprises two clamp assemblies 200 (e.g., an upper clamp assembly 200a and a lower clamp assembly 200b) and two mounting panels 300 (i.e., a first mounting panel 3001 and a second mounting panel 3002). In some embodiments, the mounting panels 300 extend outwardly from the clamp assemblies 200 (and mounting structure 70) and parallel to each other. As described in further detail below, in some embodiments, the mounting panels 300 extend outwardly in a first direction that is perpendicular to an axis defined by the mounting structure 70 (see, e.g., FIG. 7C).

As shown in FIGS. 3A-3B, in some embodiments, each pipe clamp assembly 200 includes front and rear clamp members 202, 204. In some embodiments, each clamp member 202, 204 is generally U-shaped having a recess 208, 209 that is configured to receive at least a portion of a mounting structure 70 (see, e.g., FIG. 7C). The front and rear clamp members 202, 204 are held together by two threaded bolts or rods 201 that are inserted through aligned holes 203, 205 located near the edges of the clamp members 202, 204 and secured with nuts 207. In some embodiments, the clamp members 202, 204 may comprise more than one hole 203, 205 such that the clamp assembly 200 may be mounted onto different sized mounting structures 70 (e.g., different diameter mounting poles). Tightening of the bolts 201 enables the clamp members 202, 204 to be pulled together to clamp the mounting structure 70 (e.g., a mounting pole or a leg of an antenna tower) therebetween, with the mounting structure 70 being held between recesses 208, 209 in the clamp members 202, 204. Each clamp member 202, 204 includes additional apertures 210, 211 configured to receive a fastener 250 (e.g., a carriage bolt) to secure the mounting panels 300 to the respective clamp assemblies 200 (see also, e.g., FIG. 3E).

As shown in FIGS. 3A-3D, each mounting panel 300 is configured to be secured to a clamp member 202, 204 of each clamp assembly 200 (e.g., the respective front clamp members 202 of the upper and lower clamp assemblies 200a, 200b). For example, as described in further detail below, in some embodiments, respective fasteners 250 are received through aligned apertures 210, 310a, 312a in the clamp member 202 and the mounting panels 300, respectively, to secure the mounting panels 300 to the clamp assemblies 200. As shown in FIGS. 3A-3D and FIGS. 4A-4C, in some embodiments, the two mounting panels 3001, 3002 have mirrored configurations.

The mounting panels 300 will now be described in further detail. In some embodiments, the mounting panels 300 for the mounting assembly 100 may be formed from a single piece of sheet metal (see, e.g., FIG. 5). As shown in FIGS. 3A-3D and FIGS. 4A-4C, in some embodiments, each mounting panel 300 comprises a mounting section 302 and an extension section 304. In some embodiments, the extension section 304 is configured to be secured to the clamp assemblies 200 and the mounting section 302 is configured such that different types and/or sizes of remote radio units may be mounted and secured thereto (see, e.g., FIGS. 7A-7C). In some embodiments, the mounting section 302 comprises a plurality of apertures 303. The apertures 303 are positioned in the mounting section 302 such that the mounting assembly 100 can accommodate mounting locations for a variety of different types and/or sizes of remote radio units. In addition, in some embodiments, the extension section 304 of the mounting panels 300 are configured to position the remote radio units 50 mounted to the mounting section 302 of the mounting assembly 100 a sufficient distance D2 from the mounting structure 70 (see, e.g., FIG. 7C).

As shown in FIGS. 4A-4C, in some embodiments, the mounting section 302 may comprise at least two flanged edges 309. The flanged edges 309 may help to provide additional structural support to the mounting assembly 100. In some embodiments, opposing flanged edges 309 (e.g., upper and lower flanged edges) of the mounting section 302 may comprise stabilizing members 311 extending outwardly therefrom. In some embodiments, the stabilizing members 311 include an aperture 311a As described further below, in some embodiments, after being secured to the clamping assemblies 200, corresponding stabilizing members 311 from each mounting panel 300 are configured to align with each other to receive a fastener 250 through the aligned apertures 311a, thereby providing stability between the mounting panels 300 and additional structural support to the mounting assembly 100 (see, e.g., FIG. 3A and FIG. 7C).

Still referring to FIGS. 4A-4C, the extension section 304 of each mounting panel 300 also includes flanged edges 307, 310. Similar to the mounting section 302, in some embodiments, one or more of the flanged edges 309, 310 may help to provide additional structural support to the mounting panel 300. In addition, each mounting panel 300 further comprises securing flange members 312 extending outwardly from an outer edge of the extension section 304. In some embodiments, each securing flange member 312 comprises an aperture 312a configured to receive a fastener 250. In some embodiments, opposing flanged edges 310 (e.g., upper and lower flanged edges 310) of the extension section 304 and the securing flange members 312 are configured to engage (or received therebetween) a respective clamp member 202 to secure the mounting panel 300 to the clamping assemblies 200. For example, in some embodiments, an end of each flanged edges 310 extends axially outwardly from an outer edge of the extension section 304. An aperture 310a resides in the extended end of each flanged edge 310.

As shown in FIG. 4C, in some embodiments, the securing flange members 312 are positioned a sufficient distance D from the extended end of the flanged edge 310 such that the clamp member 202 of the clamping assembly 200 may fit therebetween. During installation of the mounting panels 300 onto the clamping assemblies 200, the front clamp members 202 of the upper and lower clamp assemblies 200a, 200b are positioned between respective flanged edges 310 and securing flange members 312 such that respective apertures 310a, 312a in the flanged edges 310 and securing flange members 312 are aligned with corresponding apertures 210 in the clamp members 202. Respective fasteners 250 may then be inserted through the aligned apertures 210, 310a, 312a of the flanged edges 310, securing flange members 312 and clamp members 202 to secure the respective mounting panels 300 to the clamping assemblies 200 (see, e.g., FIGS. 3A-3D).

As further shown in FIGS. 4A-4C, in some embodiments, the mounting panel 300 includes one or more additional stabilizing members 308 extending outwardly therefrom. In some embodiments, each stabilizing member 308 comprises an aperture 308a In some embodiments, the stabilizing members 308 may reside at an angle relative to the outer edges of the extension section 304 (i.e., flanged edges 310). Similar to the stabilizing members 311 of the mounting section 302 described herein, after the mounting panels 300 are secured to the clamping assemblies 200, corresponding stabilizing members 308 from each mounting panel 300 are configured to align with each other to receive a fastener 250 through the aligned apertures 308a, thereby providing additional stability between the mounting panels 300 and additional structural support to the mounting assembly 100 (see also, e.g., FIGS. 3C-3D).

In some embodiments, the mounting panel 300 may further comprise one or more additional apertures 305 that are configured to receive a hoisting cable or similar device to allow the mounting assembly 100 to be lifted more easily at an installation site, for example, when remote radio units 50 are mounted thereon.

Referring back to FIGS. 3A-3D, during installation, the clamping assemblies 200a, 200b may be first secured to a mounting structure (e.g., a mounting pole 70 as shown in FIGS. 7A-7C). As described herein, the mounting panels 300 may then be secured a clamp member 202 of each clamping assembly 200a, 200b by positioning the respective clamp member 202 between the flanged edges 310 and securing flange members 312 and inserting a fastener 250 through the respective aligned apertures 210, 310a, 312a In some embodiments, remote radio units 50 may be first secured to each mounting panel 300 (e.g., via corresponding apertures 303 in the mounting section 302). As noted above, a hoisting device may engage with an aperture 305 in the mounting panel 300 to lift the mounting panels 300 and corresponding remote radio units 50 to the clamping assemblies 200a, 200b already installed on the mounting structure 70.

As shown in FIGS. 3C-3D, when both mounting panels 300 are secured to the clamping assemblies 200a, 200b, the stabilizing members 308, 311 and corresponding apertures 308a, 311a of each mounting panel 300 may be aligned and respective fasteners 250 inserted therethrough to secure the two mounting panels 300 together, thereby providing additional stability between the mounting panels 300 and additional structural support to the mounting assembly 100 (e.g., may help to prevent rotation of the assembly 100).

As noted above, in some embodiments, the mounting panels 300 for the mounting assembly 100 may be formed from a single piece of sheet metal. FIG. 5 illustrates the cut piece of sheet metal prior to bending to form the mounting panel 300. According to embodiments of the present invention, a reduced number of bends (i.e., 12 bends) is needed to form each mounting panel 300 from a single piece of sheet metal compared to other mounting panels (as described herein), thereby making the mounting assembly 100 potentially more robust than other potential designs.

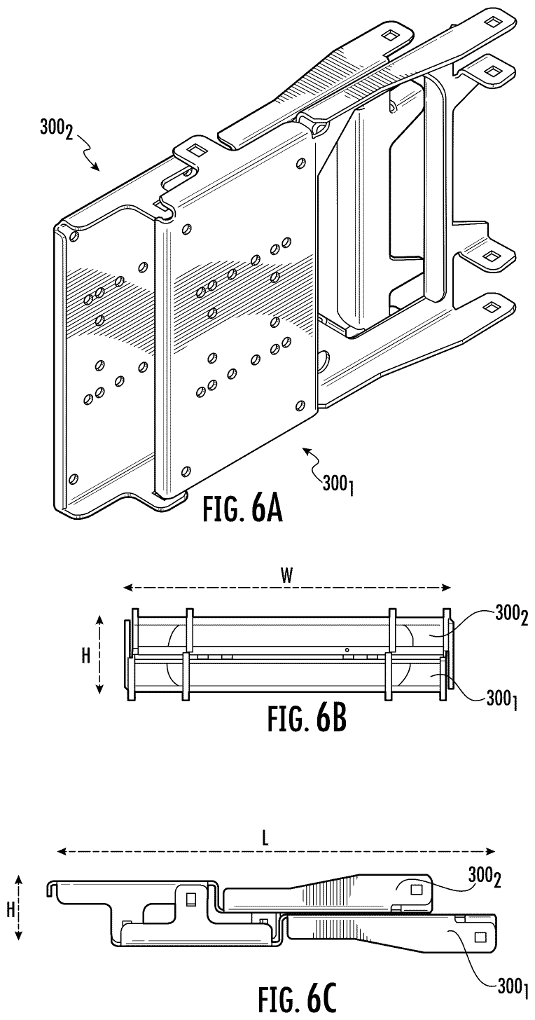

FIGS. 6A-6C illustrate how two mounting panels 3001, 3002 may be stacked together to provide optimized stacking space, thereby helping to reduce shipping (packing) costs. For example, in some embodiments, when stacked together, the two mounting panels 3001, 3002 have may have an overall length (L) in a range of between about 18 inches and 22 inches, an overall width (W) in a range of between about 10 inches and about 14 inches, and an overall height (H) in a range of between about 3 inches and about 4 inches.

As described herein, FIGS. 7A-7C illustrate the mounting assembly 100 of the present invention secured to a mounting structure 70 (e.g., a mounting pole) via clamping assemblies 200 and having two remote radio units 50 mounted in a back-to-back orientation. As shown in FIG. 7C, according to embodiments of the present invention, the remote radio units 50 are mounted to the mounting sections 302 of the mounting panels 300 and the extension sections 304 of the mounting panels 300 position the remote radio units 50 a sufficient distance D2 from the mounting structure 70.

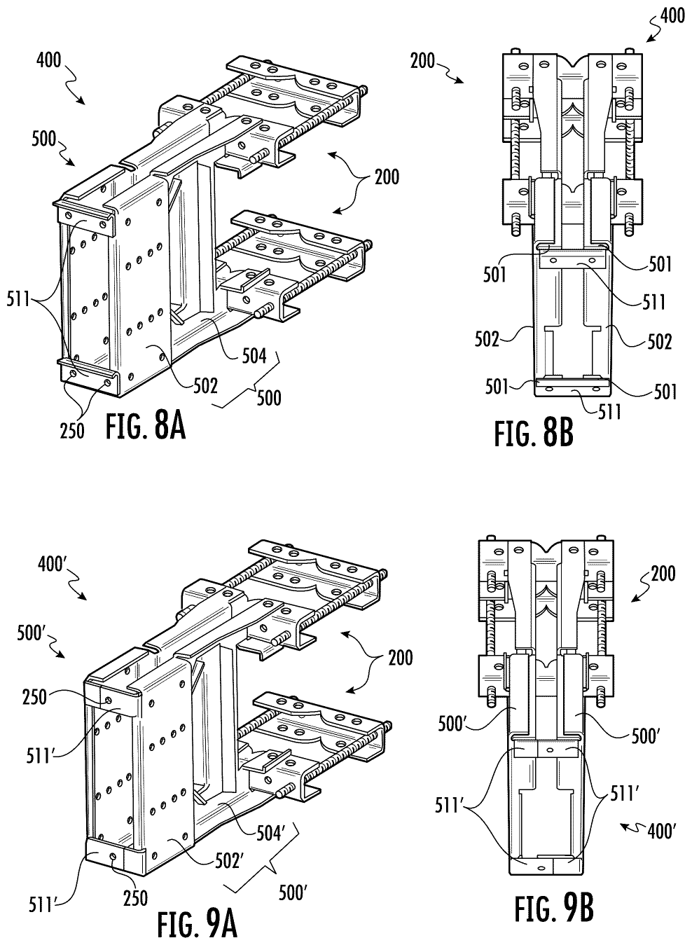

Referring now to FIGS. 8A-8B, FIGS. 9A-9B, and FIGS. 10A-10B, alternative mounting assemblies 400, 400, 400″ according to embodiments of the present invention are illustrated. Properties and/or features of the mounting assemblies 400, 400, 400″ may be as described above in reference to the mounting assembly 100 and duplicate discussion thereof may be omitted herein for the purposes of discussing FIGS. 8A-8B, FIGS. 9A-9B, and FIGS. 10A-10B.

As shown in FIGS. 8A-8B, FIGS. 9A-9B, and FIGS. 10A-10B, similar to mounting assembly 100 described herein, each of the alternative mounting assemblies 400, 400, 400″ comprise mounting panels 500, 500, 500″ configured to be secured to the clamping assemblies 200. The difference between each of these mounting assemblies 400, 400, 400″ and the mounting assembly 100 described herein is the configuration and/or position of stabilizing members 511, 511′, 511″ used to coupled together the mounting panels 500, 500, 500′ and provide additional stability between the mounting panels 500, 500, 500″ and additional structural support to the respective mounting assembly 400, 400, 400″.

In FIGS. 8A-8B, the alternative mounting assembly 400 is illustrated. Similar to the mounting assembly 100 described herein, as shown in FIGS. 8A-8B, the mounting panels 500 of the mounting assembly 400 may each include a mounting section 502 and an extension section 504. In some embodiments, the mounting assembly 400 further comprises two stabilizing members 511 that are configured to couple together the mounting panels 500. For example, in some embodiments, each mounting panel 500 may comprise one or more tab members 501 extending from a front edge of the mounting section 502. Each tab member 501 of one mounting panel 500 is aligned with a corresponding tab member 501 of the other mounting panel 500. Each stabilizing member 511 is sized and configured to fit between the mounting panels 500 and be secured to a respective tab member 501 from each mounting panel 500, for example, via fasteners 250. Similar to the stabilizing members 311 for the mounting assembly 100, the stabilizing members 511 for the mounting assembly 400 help to provide stability between the two mounting panels 500, as well as provide additional structural support to the mounting assembly 400 (e.g., helps to prevent rotation of the assembly 400).

In FIGS. 9A-9B, another alternative mounting assembly 400′ is illustrated. As shown in FIGS. 9A-9B, similar to the mounting assemblies 100, 400 described herein, the mounting panels 500 of the mounting assembly 400′ may each include a mounting section 502 and an extension section 504. In addition, in some embodiments, the mounting assembly 400′ further comprises stabilizing members 511′ that are configured to couple together the mounting panels 500. The mounting assembly 400 differs from the mounting assembly 400 in that the stabilizing members 511′ comprise corresponding tab members that are coupled to or integral with the mounting section 502′. The tab members (stabilizing members 511′) extend from a front edge of the mounting section 502 of each mounting panel 500. Each tab member (stabilizing member 511′) from one mounting panel 500 is configured to overlap with a corresponding tab member (stabilizing member 511′) of the other mounting panel 500 such that a fastener 250 may secure the corresponding tab members (stabilizing members 511′) from each mounting panel 500 together. Similar to the stabilizing members 511 for the mounting assembly 400, the stabilizing members 511′ help to provide stability between the two mounting panels 500, as well as provide additional structural support to the mounting assembly 400.

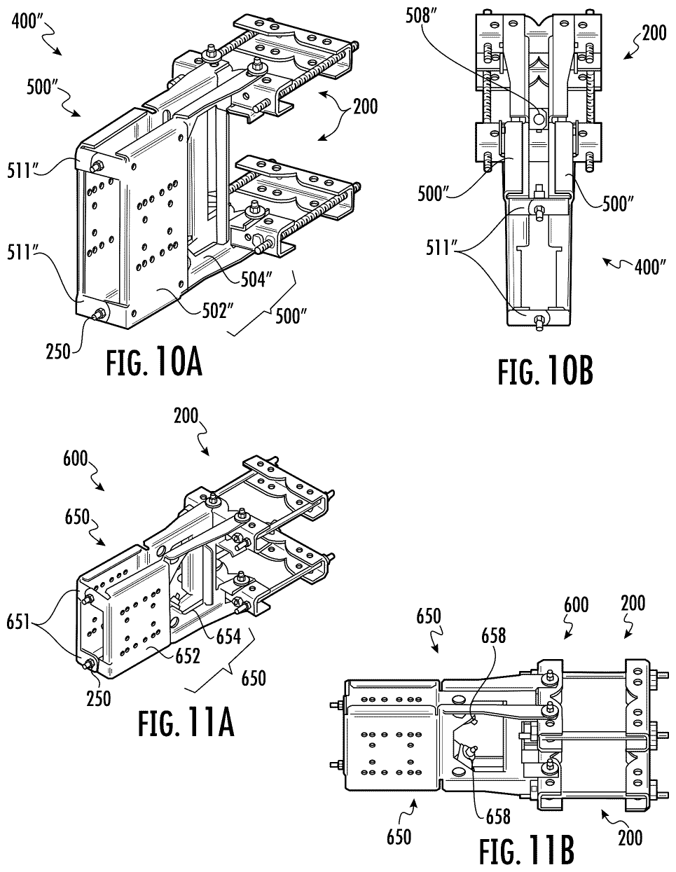

In FIGS. 10A-10B, another alternative mounting assembly 400″ is illustrated. As shown in FIGS. 10A-10B, the mounting panels 500″ for mounting assembly 400″ are similar to the other mounting panels 300, 500, 500 described herein and include a mounting section 502″ and an extension section 504′″. Similar to mounting assembly 400, the stabilizing members 511″ of mounting assembly 400″ comprise corresponding tab members that extend from a front edge of the mounting section 502″ of each mounting panel 500′ and are configured to overlap such that a fastener 250 may secure corresponding stabilizing members 511″ from each mounting panel 500 together. The mounting assembly 400′ differs from mounting assembly 400 in that the mounting assembly 400″ further comprises one or more additional stabilizing members 508 extending from the extension section 504″. The additional stabilizing members 508′ are similar to the stabilizing members 308 for mounting assembly 100 described herein. Together, the stabilizing members 508′, 511″ help to provide stability between the two mounting panels 500′ “, as well as provide additional structural support to the mounting assembly 400”.

Referring to FIGS. 11A-11B, another alternative mounting assembly 600 is illustrated. As shown in FIGS. 11A-11B, the mounting assembly 600 is similar to other mounting assemblies described herein having two mounting panels 650 and clamping assemblies 200. In addition, in some embodiments, each mounting panel 650 has a mounting section 652 and an extension section 654. The mounting panels 650 are similar to the mounting panels 500″ described herein and shown in FIGS. 10A-10B in which the mounting panels 650 are coupled together via stabilizing (tab) members 651, 658 that extend from each mounting panel 650 and overlap to receive a fastener 250. The mounting assembly 600 differs from the mounting assemblies 400, 400, 400″ in the overall size of the mounting assembly 600 is more compact (i.e., smaller) which can provide cost advantages, while still providing sufficient strength to support the remote radio units 50 mounted thereon.

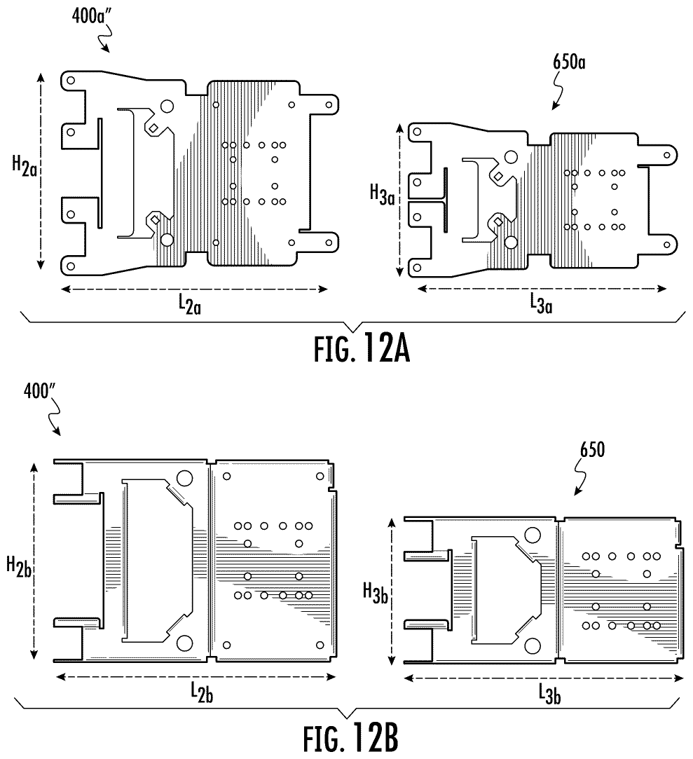

For example, as shown in FIGS. 12A-12B, a comparison of the dimensions of mounting assembly 400″ and mounting assembly 600 are illustrated. FIG. 12A illustrates the dimensions for an initial piece of sheet metal 400a″, 650a used to form the respective mounting assemblies 400′, 650 (i.e., before bending). As shown in FIG. 12A, in some embodiments, the initial piece of sheet metal 400a″ for mounting assembly 400″ has an overall height (H₂ₐ) in a range of between about 14 inches and about 17 inches and an overall length (L₂ₐ) in a range of between about 20 inches and about 22 inches. In some embodiments, the initial sheet metal 400a′ has an overall height (H₂ₐ) of about 15.5 inches and an overall length (L₂ₐ) of about 21 inches. In contrast, in some embodiments, the initial piece of sheet metal 650a for mounting assembly 650 has an overall height (H₃ₐ) in a range of between about 11 inches and about 13 inches and an overall length (L₃ₐ) in a range of between about 20 inches and about 22 inches. In some embodiments, the initial piece of sheet metal 650a for mounting assembly 650 has an overall height (H₃ₐ) of about 12 inches and an overall length (L₃ₐ) of about 21 inches.

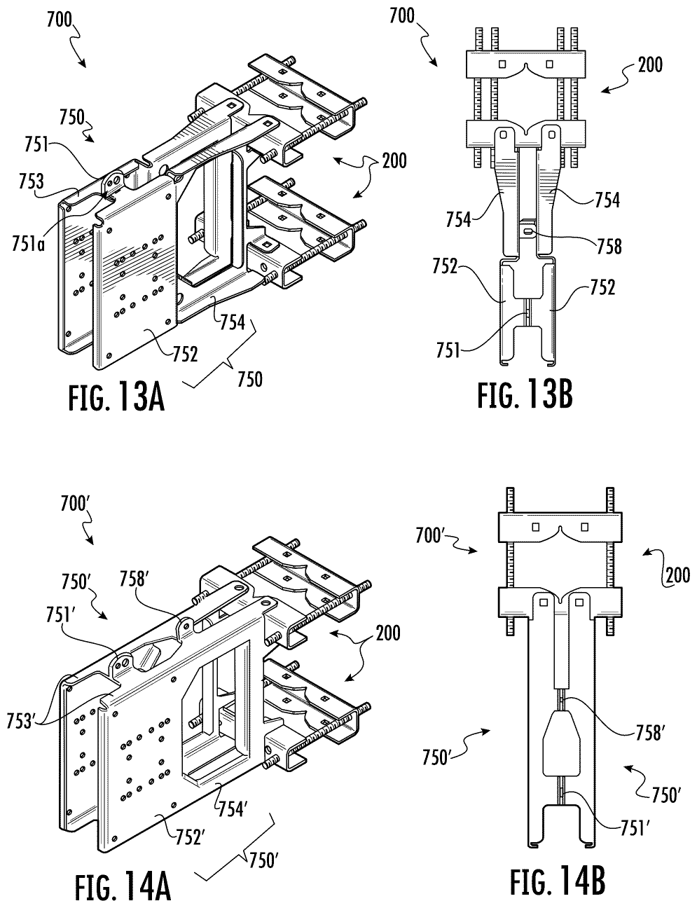

As shown in FIG. 13A, in some embodiments, the resultant mounting assembly 400′ (i.e., after bending) has an overall height (H_{2b}) in a range of between about 11 inches and about 13 inches and an overall length (L_{2b}) in a range of between about 16 inches and about 18 inches. In some embodiments, the resultant mounting assembly 400″ has an overall height (H_{2b}) of about 12.5 inches and an overall length (L_{2b}) of about 17.3 inches. Whereas, in some embodiments, the resultant mounting assembly 650 (i.e., after bending) has an overall height (H_{3b}) in a range of between about 7 inches and about 10 inches and an overall length (L_{3b}) in a range of between about 16 inches and about 18 inches. In some embodiments, the resultant mounting assembly 650 has an overall height (H_{3b}) of about 8.5 inches and an overall length (L_{3b}) of about 17.3 inches.

Referring now to FIGS. 13A-13B and FIGS. 14A-14B, alternative mounting assemblies 700, 700 according to embodiments of the present invention are illustrated. Properties and/or features of the mounting assemblies 700, 700′ may be as described above in reference to the mounting assembly 100 and duplicate discussion thereof may be omitted herein for the purposes of discussing FIGS. 13A-13B and FIGS. 14A-14B.

As shown in FIGS. 13A-13B and FIGS. 14A-14B, similar to other mounting assemblies described herein, each of the alternative mounting assemblies comprise two mounting panels 750, 750′ configured to be secured to two clamping assemblies 200. The difference between each of these mounting assemblies 700, 700 and the mounting assemblies described herein is the configuration and/or position of stabilizing members 751, 753 used to coupled together the mounting panels 750, 750 and provide additional stability between the mounting panels 750, 750 and additional structural support to the respective mounting assembly 700, 700.

As shown in FIGS. 13A-13B, similar to mounting assembly 100, in some embodiments, the mounting section 752 of each mounting panel 750 may comprise at least two flanged edges 753. The flanged edges 753 may help to provide additional structural support to the mounting assembly 700. In some embodiments, opposing flanged edges 753 (e.g., upper and lower flanged edges) of the mounting section 752 may comprise stabilizing members 751 which each include an aperture 751a. The stabilizing members 751 differ from the stabilizing members 311 of mounting assembly 100 in that the stabilizing members 751 are bent upwardly to align with a corresponding stabilizing members 751 from each mounting panel 750. A fastener 250 is received through the aligned apertures 751a to secure the mounting panels 750 together, thereby providing stability between the mounting panels 750 and additional structural support to the mounting assembly 700.

As further shown in FIGS. 13A-13B, in some embodiments, each mounting panel 750 includes one or more additional stabilizing members 758 extending outwardly therefrom. In some embodiments, the stabilizing members 758 may reside at an angle relative to the outer edges of the extension section 754. Similar to the stabilizing members 751, corresponding stabilizing members 758 from each mounting panel 750 are configured to align with each other to receive a fastener 250, thereby providing additional stability between the mounting panels 750 and additional structural support to the mounting assembly 700.

As shown in FIGS. 14A-14B, similar to mounting assembly 700, in some embodiments, opposing flanged edges 753 (e.g., upper and lower flanged edges) of the mounting section 752 for mounting assembly 700′ may comprise stabilizing members 751′ which each include an aperture 751a′. The stabilizing members 751′ are bent upwardly to align with a corresponding stabilizing members 751′ from each mounting panel 750. A fastener 250 is received through the aligned apertures 751a′ to secure the mounting panels 750 together, thereby providing stability between the mounting panels 750 and additional structural support to the mounting assembly 700.

The mounting assembly 700 differs from mounting assembly 700 in that, in some embodiments, the mounting panels 750 (i.e., mounting section 752′ and the extension section 754) may have a more planar outer surface compared to the mounting panels 750 of mounting assembly 700. In addition, as shown in FIGS. 14A-14B, in some embodiments, the additional stabilizing members 758 for the mounting panels 750 of mounting assembly 700′ may be moved to the opposing flanged edges 753′ which now continuously extend the length of the mounting panel 750. The additional stabilizing members 758 may be similar to the stabilizing members 751′ described herein (i.e., bent upwardly to align with a corresponding stabilizing members 758 from each mounting panel 750 and received a fastener 250 to further secure the mounting panels 750 together).

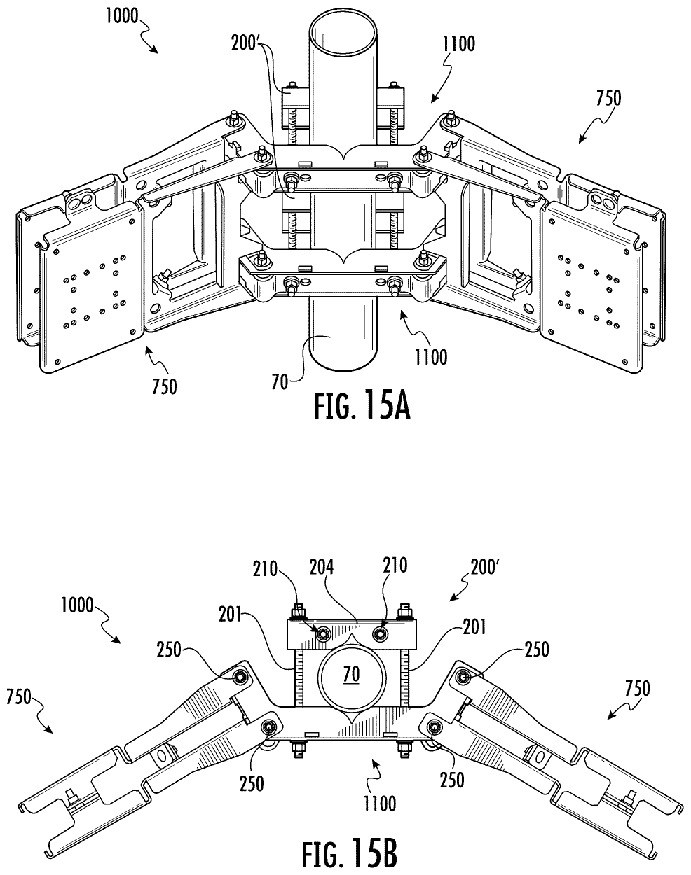

Referring to FIGS. 15A-15B, a remote radio unit mounting kit 1000 according to embodiments of the present invention is illustrated. As shown in FIGS. 15A-15B, in some embodiments, the mounting kit 1000 includes a mounting assembly comprising a pair of mounting brackets 1100 and corresponding clamping assemblies 200. The mounting brackets 1100 and clamping assemblies 200 are configured to secure the mounting kit 1000 to a mounting structure 70 (e.g., a mounting pole).

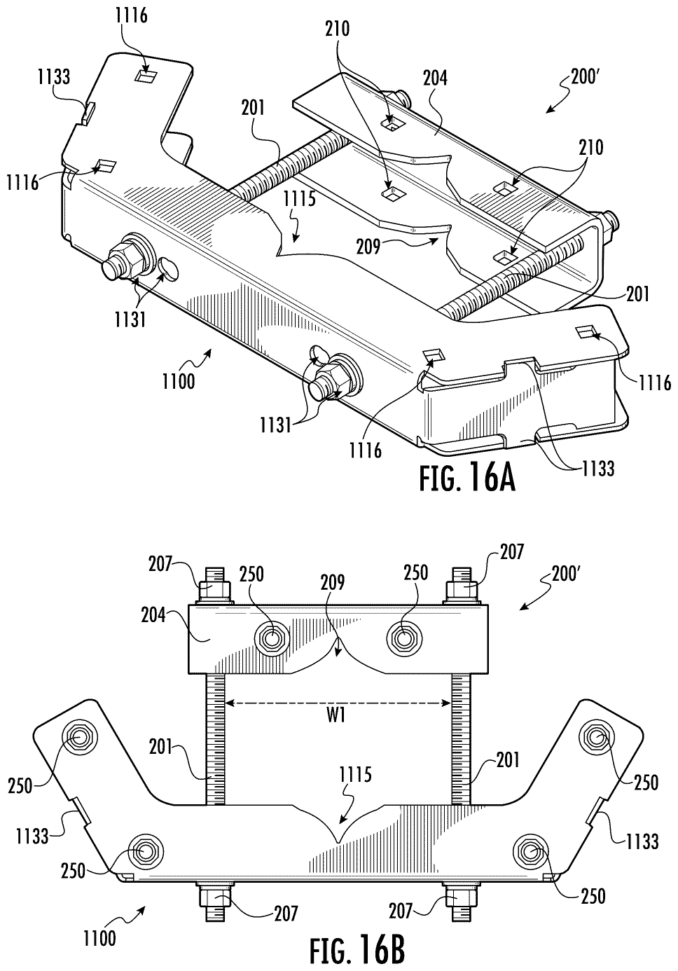

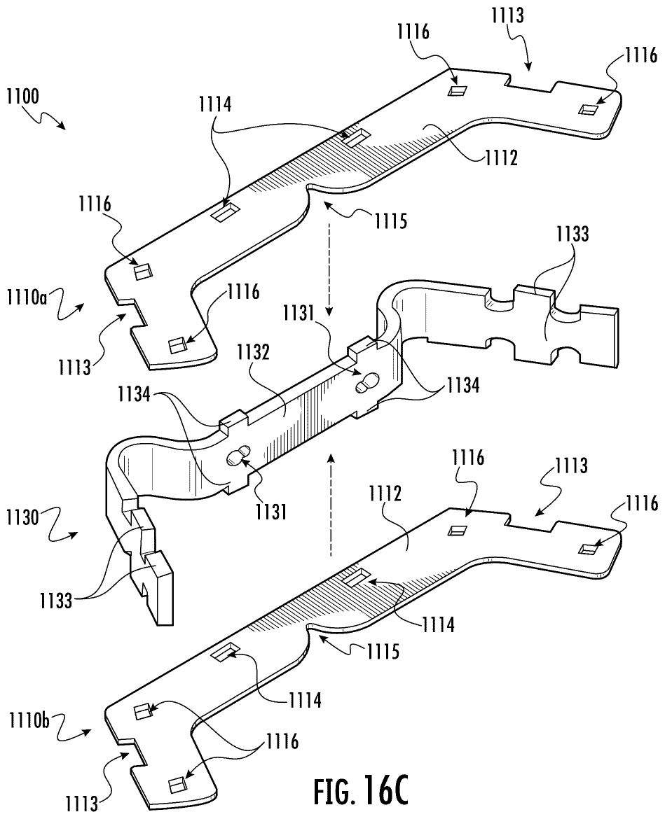

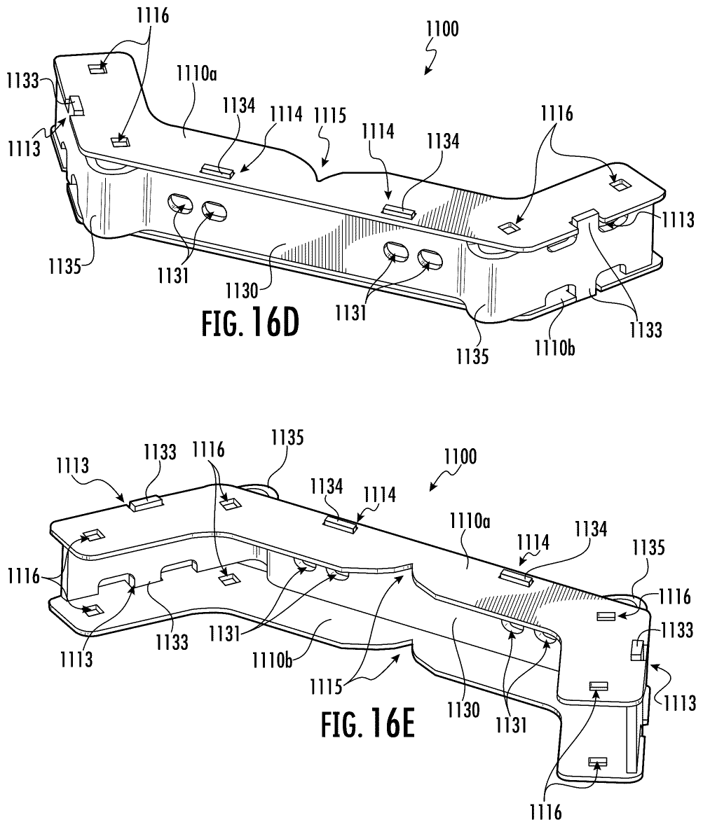

As shown in FIG. 15B, in some embodiments, each clamp assembly 200 includes a clamp member 204 (similar to the clamp assembly 200 described herein). In some embodiments, the clamp member 204 is generally U-shaped having a recess 209 that is configured to receive at least a portion of the mounting structure 70. The clamp member 204 and corresponding mounting bracket 1100 may be held together by two threaded bolts or rods 201 that are inserted through holes 1131 in the mounting bracket 1100 (see, e.g., FIGS. 16A-16C) and holes (not visible) in clamp member 204 and secured with nuts 207 (similar to other mounting assemblies described herein). As described in further detail below, in some embodiments, the mounting brackets 1100 (and clamp members 204) may comprise more than one hole 1131 (see, e.g., FIGS. 16B-16C) to accommodate different sized mounting structures 70 (e.g., different diameter mounting poles). Tightening of the bolts 201 enables the clamp members 204 and mounting brackets 1100 to be pulled together to clamp the mounting structure 70 (e.g., a mounting pole or a leg of an antenna tower) therebetween, with the mounting structure 70 being held between recesses 209 in the clamp members 204 (and recesses 1115 in the mounting brackets 1100, see, e.g., FIGS. 16A-16C).

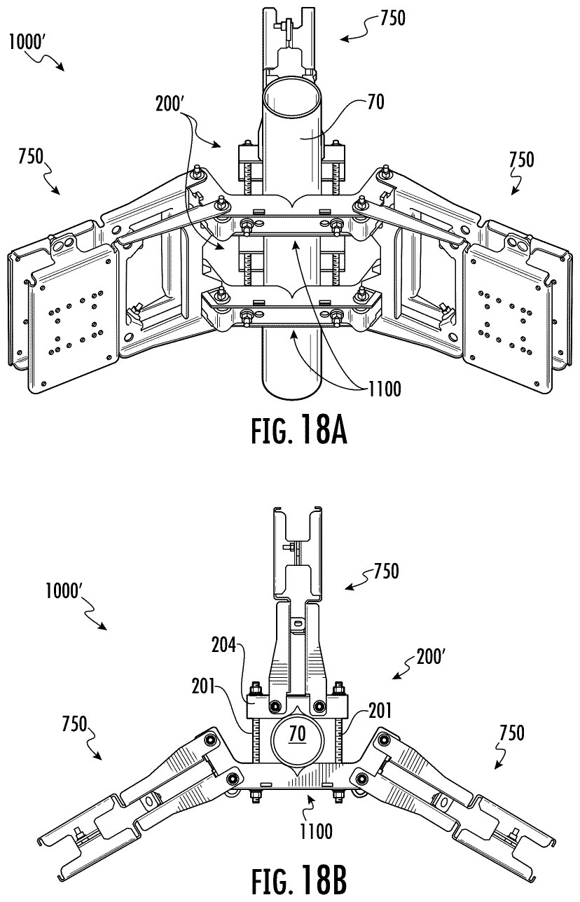

As described in further detail below, in some embodiments, each clamp member 204 may include additional apertures 210 configured to receive a fastener 250 (e.g., a carriage bolt) to secure an additional pair of mounting panels 750 to the mounting kit 1000 (i.e., clamp assembly 200) (see also, e.g., FIGS. 18A-18B).

According to embodiments of the present invention, the mounting kit 1000 also includes at least two pairs of mounting panels 750 described herein. As further shown in FIGS. 15A-15B, in some embodiments, the pairs of mounting panels 750 are configured to be secured to opposing ends of the mounting brackets 1100. While mounting panels 750 are shown in FIGS. 15A-15B, it is noted that any of the mounting panels described herein could be used with the remote radio unit mounting kit 1000 of the present invention.

FIGS. 16A-16B illustrate one of the mounting brackets 1100 engaged with a corresponding clamp assembly 200 according to embodiments of the present invention. As shown in FIG. 16B, in some embodiments, the mounting bracket 1100 is configured to fit a width W1 (e.g., a diameter of a mounting pole) between the threaded rods 201. For example, in some embodiments, the mounting bracket 1100 is configured to fit a width W1 (or mounting pole diameter) up to about 6 inches.

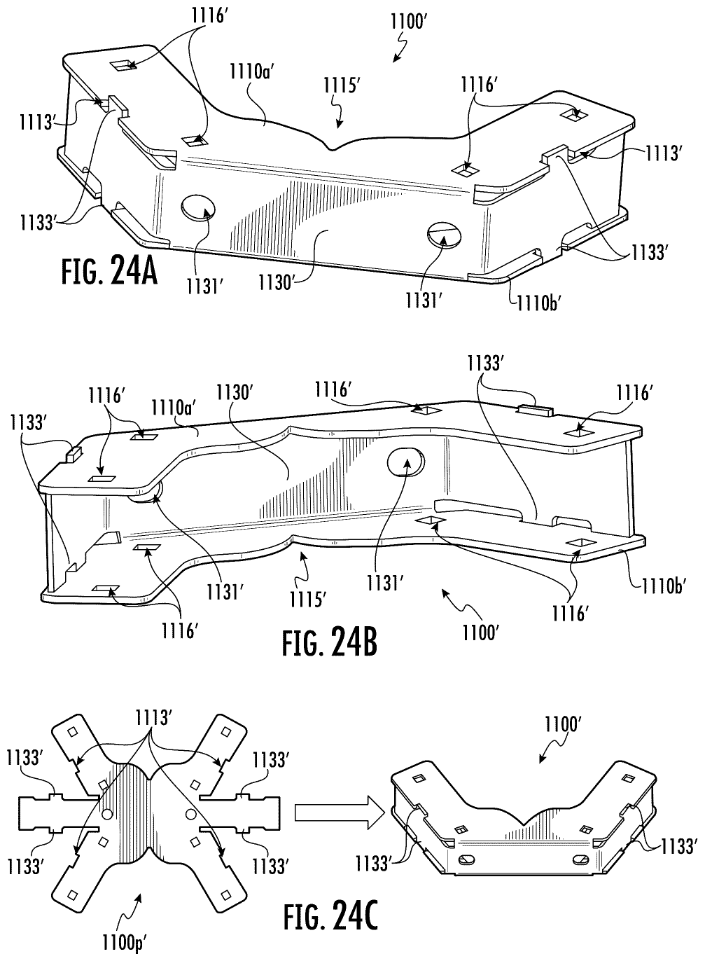

FIGS. 16C-16E illustrate one of the mounting brackets 1100 in greater detail. As shown in FIGS. 16C-16E, in some embodiments, the mounting bracket 1100 includes main bracket member 1130 coupled between an upper plate 1110a and a lower plate 1110b. In other embodiments, the mounting bracket 1100 may be formed from a single piece of steel which is bent to form sections of the mounting bracket 1100 equivalent to the main bracket member 1130 and upper and lower plates 1110a, 1110b (see, e.g., FIGS. 16A-16B and FIG. 24C). In some embodiments, the upper and lower plates 1110a, 1110b are positioned generally parallel to each other with the main bracket member 1130 positioned generally perpendicular to the upper and lower plates 1110a, 1110b. The main bracket member 1130 includes at least two apertures 1131. Each aperture 1131 is configured to receive a respective bolt 201 of the clamp assemblies 200 in order to secure the mounting brackets 1100 to the clamp members 204 (and mounting structure 70).

In some embodiments, the upper and lower plates 1110a, 1110b are identical. In some embodiments, the upper and lower plates 1110a, 1110b have a generally C-shaped main body 1112. In some embodiments, a recess 1115 resides in a generally central section of the main body 1112. As discussed above, the recesses 1115 of the plates 1110a, 1110b may be configured to receive at least a portion of the mounting structure 70, with the mounting structure 70 being held between the recesses 1115 of the plates 1110a, 1110b and the corresponding the recesses 209 in the clamp members 204, i.e., when mounted thereon.

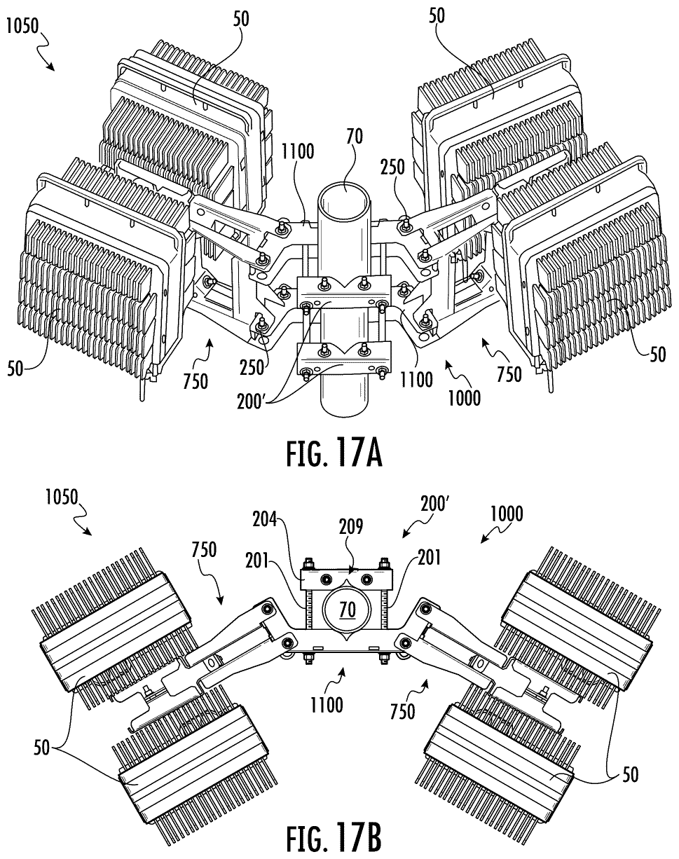

As shown in FIGS. 16C-16E, in some embodiments, the main body 1112 of the upper and lower plates 1110a, 1110b may comprise additional recesses 1113 at opposing ends of the upper and lower plates 1110a, 1110b. In some embodiments, each recess 1113 is sized and configured to receive a corresponding protrusion 1133 extending outwardly from the main bracket member 1130. In some embodiments, the protrusions 1133 and corresponding recesses 1113 provide a location for the upper and lower plates 1110a, 1110b to be secured (e.g., welded) to the main bracket member 1130. The protrusions 1133 may also provide a securement location (e.g., welding location) when the mounting bracket 1100 is formed (bent) from a single piece of steel (see, e.g., FIG. 24C). In addition, as further shown in FIGS. 16C-16E, in some embodiments, the main bodies 1112 of the upper and lower plates 1110a, 1110b may each comprise a plurality of apertures 1114, 1116. Some of the apertures 1114 are configured to received additional protrusions 1134 extended outwardly from the main bracket member 1130, thereby providing additional locations for the upper and lower plates 1110a, 1110b to be secured (e.g., welded) to the main bracket member 1130. As described in further detail below, in some embodiments, the other apertures 1116 in the upper and lower plates 1110a, 1110b are configured to receive fasteners 250 to secure the mounting panels 750 to the mounting brackets 1100 (see, e.g., FIG. 16B, FIGS. 15A-15B and FIGS. 17A-17B).

Referring to FIGS. 17A-17B, a mounting assembly 1050 according to embodiments of the present invention is illustrated. In some embodiments, the mounting assembly 1050 utilizes the mounting kit 1000 described above to secure four (4) remote radio units 50 to a mounting structure 70 (e.g., mounting pole). As shown in FIGS. 17A-17B, the mounting brackets 1100 and clamp assemblies 200 of the mounting kit 1000 are secured to the mounting structure 70 (i.e., the mounting structure 70 is clamped between the mounting brackets 1100 and clamp members 204 of the clamp assemblies 200). Mounting panels 750 (or similar mounting panels described herein) are secured to opposing ends of the mounting brackets 1100 via fasteners 250. The remote radio units 50 are secured back-to-back on the mounting panels 750 as described herein.

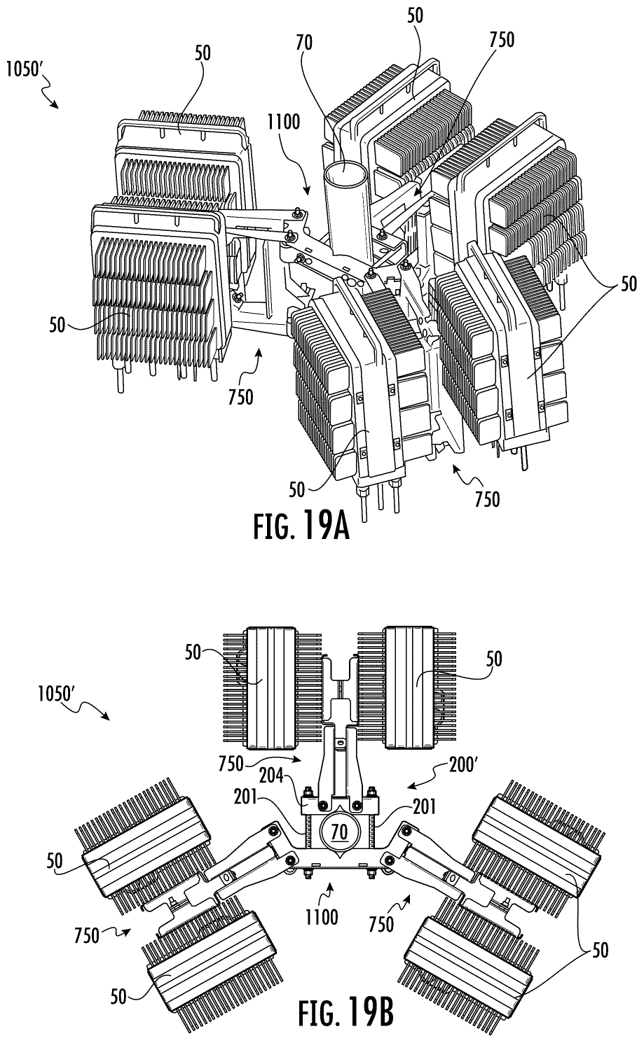

Referring to FIGS. 18A-18B, in some embodiments, the mounting kit 1000 described herein may be configured such that two additional remote radio units 50 may be secured thereon. As shown in FIGS. 18A-18B, in some embodiments, the alternative mounting kit 1000 is configured such that an additional pair of mounting panels 750 may be secured to the clamp member 204 of the clamp assembly 200′, thereby allowing for a total of six (6) remote radio units 50 to be secured to a mounting structure 70 (see, e.g., FIGS. 19A-19B). The additional pair of mounting panels 750 may be secured to the clamp member 204 via fasteners 250, similar to other mounting panels described herein (see, e.g., FIG. 3E).

Referring to FIGS. 19A-19B, a mounting assembly 1050 according to embodiments of the present invention is illustrated. In some embodiments, the mounting assembly 1050 utilizes the mounting kit 1000 described above and is configured to secure up to six (6) remote radio units 50 to a mounting structure 70 (e.g., mounting pole). As shown in FIGS. 19A-19B, the mounting brackets 1100 and clamp assemblies 200′ of the mounting kit 1000′ are secured to the mounting structure 70 (i.e., the mounting structure 70 is clamped between the mounting brackets 1100 and clamp members 204 of the clamp assemblies 200). Mounting panels 750 (or similar mounting panels described herein) are secured to opposing ends of the mounting brackets 1100 and the clamp members 204 via fasteners 250. The remote radio units 50 are secured back-to-back on the mounting panels 750 as described herein.

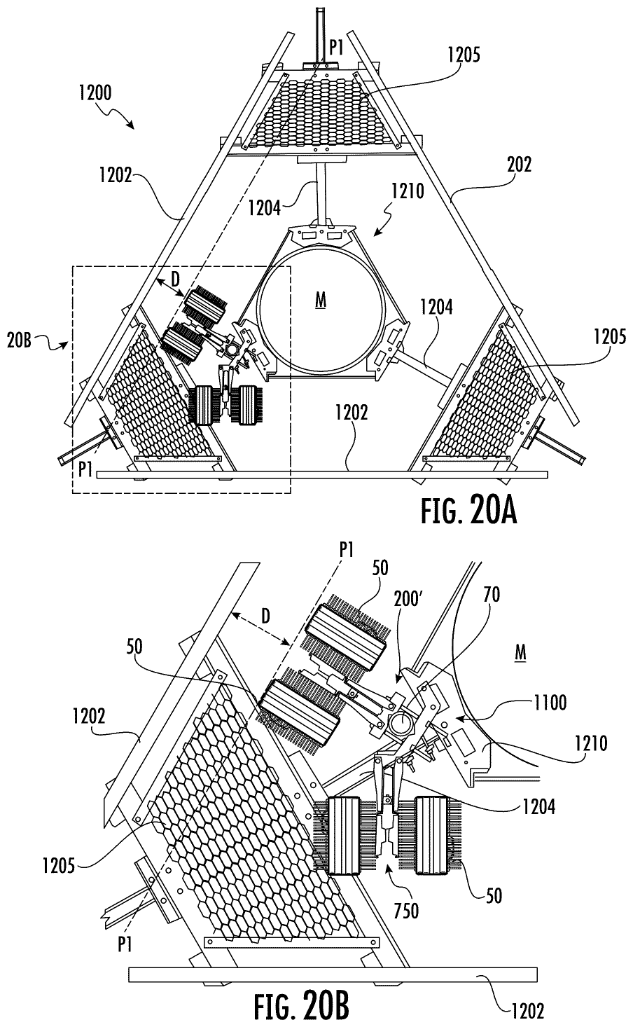

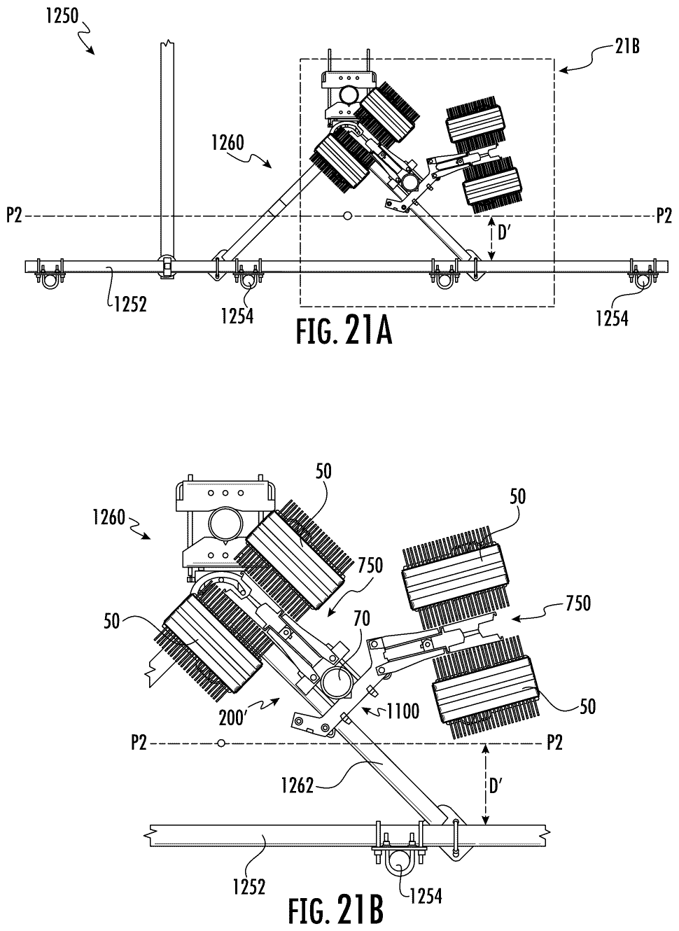

FIGS. 20A-20B and FIGS. 21A-21B illustrate the capability of the mounting kits 1000, 1000′ described herein to meet carrier spacing requirements when used on a monopole platform assembly 1200 or on a sector frame assembly 1250 according to embodiments of the present invention. It is difficult for current mounting kits to meet carrier spacing requirements, in particular, when larger size remote radio units are used. The mounting kits 1000, 1000 of the present invention provide a compact design with a lower risk of passive intermodulation (PIM), as well as reduced cost.

As shown in FIGS. 20A-20B and FIGS. 21A-21B, the mounting kits 1000, 1000 also provide different mounting points on the monopole platform assembly 1200 and sector frame assembly 1250, thereby allowing for flexibility to achieve carrier spacing requirements. For example, as shown in FIGS. 20A-20B, a monopole platform assembly 1200 is illustrated. In some embodiments, the monopole platform assembly 1200 comprises a plurality of horizontal members 1202 adjustable arm members 1204, and grating members 1205. In some embodiments, the monopole platform assembly 1200 is secured to a monopole M via ring mount kit 1210. In some embodiments, the mounting kit 1000 may be secured to one or more of the adjustable arm members 1204. As shown in FIGS. 20A-20B, the mounting kit 1000 can be positioned such that the remote radio units 50 reside a sufficient distance D from a horizontal member 1202 of the monopole platform assembly 1200 in order to meet specific carrier spacing requirements (e.g., an outer edge of the remote radio units 50 are positioned along plane P1). In some embodiments, the mounting kit 1000 positions the remote radio unit(s) 50a distance D of at least 12 inches from the horizontal pipe member 1202.

As shown in FIGS. 21A-21B, in some embodiments, the mounting kit 1000 may allow for similar positioning of the remote radio units 50 on a sector frame assembly 1250. In some embodiments, the sector frame assembly 1250 comprises a plurality of horizontal and vertical members 1252, 1254 and an offset assembly 1260. In some embodiments, the mounting kit 1000 may be secured to an extension member 1262 of the offset assembly 1260. As shown in FIGS. 21A-21B, the mounting kit 1000 can be positioned such that the remote radio units 50 reside a sufficient distance D′ from the horizontal member 1252 of the sector frame assembly 1250 in order to meet specific carrier spacing requirements (e.g., an outer edge of the remote radio units 50 are positioned along plane P2). In some embodiments, the mounting kit 1000 positions the remote radio unit(s) 50a distance D′ of at least 12 inches from the horizontal pipe member 1252.

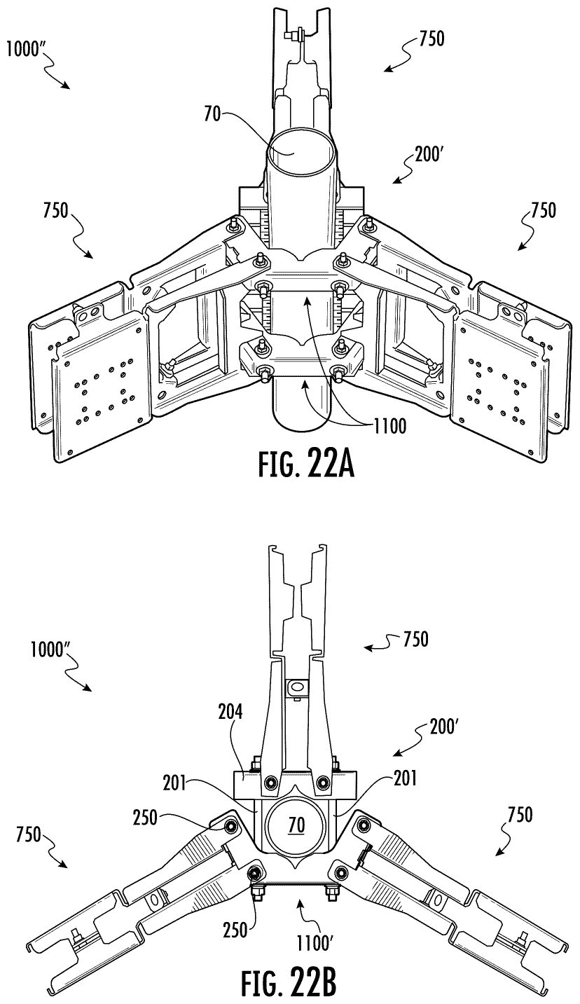

Referring to FIGS. 22A-22B, an alternative remote radio unit mounting kit 1000″ according to embodiments of the present invention is illustrated. Properties and/or features of the mounting kit 1000″ may be as described above in reference to the mounting kits 1000, 1000 described herein and duplicate discussion thereof may be omitted herein for the purposes of discussing the alternative mounting kit 1000″.

As shown in FIGS. 22A-22B, FIGS. 23A-23B, and FIGS. 24A-24C, the mounting kit 1000″ is similar to the mounting kits 1000, 1000 described herein and includes a mounting assembly comprising a pair of mounting brackets 1100 and corresponding clamping assemblies 200′. The mounting brackets 1100 and clamping assemblies 200 are configured to secure the mounting kit 1000′ to a mounting structure 70 (e.g., a mounting pole). The mounting kit 1000″ differs from the mounting kits 1000, 1000 in that the configuration of the mounting brackets 1100 provide for a more compact design compared to the mounting bracket 1100 described herein.

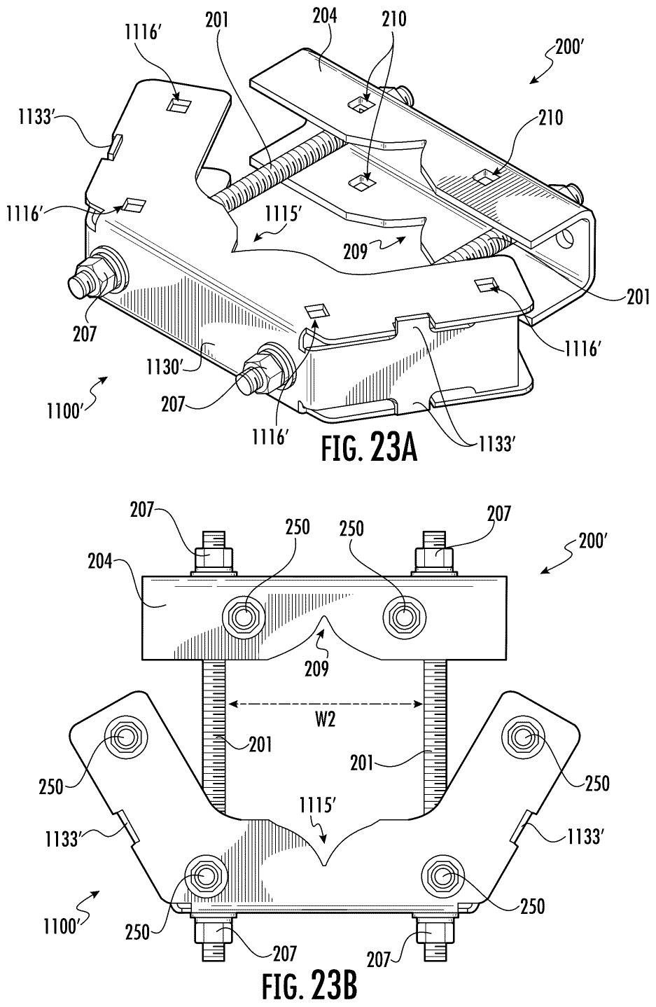

Referring to FIGS. 23A-23B and FIGS. 24A-24C, the mounting bracket 1100 includes main bracket section 1130 coupled between an upper plate section 1110a′ and a lower section 1110b′. As shown in FIGS. 24A-24C, in some embodiments, the mounting bracket 1100′ may be formed from a single piece of steel which is bent to form the main bracket section 1130 and upper and lower plate sections 1110a′, 1110b′. In other embodiments, the mounting bracket 1100 may include individual members that are welded together (similar to the main bracket member 1130 and upper and lower plates 1110a, 1110b for mounting brackets 1100 described herein). In some embodiments, the upper and lower plate sections 1110a′, 1110b′ are positioned generally parallel to each other with the main bracket section 1130 positioned generally perpendicular to the upper and lower plate sections 1110a′, 1110b′. The main bracket section 1130 includes at least two apertures 1131′. Each aperture 1131′ is configured to receive a respective bolt 201 of the clamp assemblies 200′ in order to secure the mounting brackets 1100 to the clamp members 204 (and mounting structure 70).

In some embodiments, the upper and lower plate sections 1110a′, 1110b′ are identical. In some embodiments, the upper and lower plate sections 1110a′, 1110b′ are generally C-shaped. In some embodiments, a recess 1115′ resides in a generally central section of the upper and lower plate sections 1110a, 1110b′. The recesses 1115′ may be configured to receive at least a portion of the mounting structure 70, with the mounting structure 70 being held between the recesses 1115′ and the corresponding the recesses 209 in the clamp members 204, i.e., when mounted thereon.

In some embodiments, the upper and lower plate sections 1110a′, 1110b′ may comprise additional recesses 1113 at opposing ends of the upper and lower plates 1110a, 1110b. In some embodiments, each recess 1113′ is sized and configured to receive a corresponding protrusion 1133′ extending outwardly from the main bracket section 1130. In some embodiments, the protrusions 1133′ and corresponding recesses 1113′ provide a location for the upper and lower plate sections 1110a′, 1110b′ to be secured (e.g., welded) to the main bracket section 1130, for example, when the mounting bracket 1100′ is formed (bent) from a single piece of steel (see, e.g., FIG. 24C). In addition, in some embodiments, the upper and lower plate sections 1110a′, 1110b′ may each comprise a plurality of apertures 1116 that are configured to receive fasteners 250 to secure the mounting panels 750 to the mounting brackets 1100 (see, e.g., FIGS. 22A-22B, FIG. 23B, FIGS. 25A-25B).

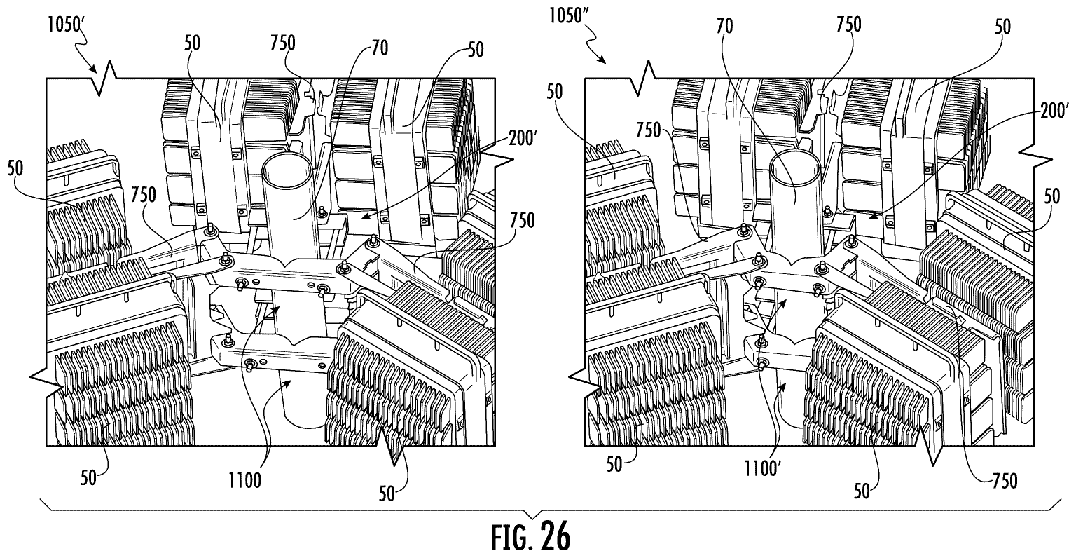

As noted above, the mounting kit 1000″ differs from the mounting kits 1000, 1000 in that the configuration of the mounting brackets 1100 provide for a more compact design compared to the mounting bracket 1100 described herein. As shown in FIG. 23B, in some embodiments, the mounting bracket 1100′ is configured to fit a width W2 (e.g., a diameter of a mounting pole) between the threaded rods 201. In some embodiments, the mounting bracket 1100 is configured to fit a width W2 that may be less than the width W1 the mounting bracket 1100 described herein is configured to fit. For example, in some embodiments, the mounting bracket 1100 is configured to fit a width W2 (or mounting pole diameter) up to about 4.5 inches. However, the widths W1, W2 of the mounting brackets 1100, 1100′ can vary based on customer requirements. The smaller overall width W2 allows the mounting bracket 1100 (and remote radio units 50 mounted thereon) to be positioned closer to the mounting structure 70 compared to the mounting bracket 1100 (see, e.g., FIG. 26), thereby saving space. Some advantages may include the mounting bracket 1100 being cheaper and lighter, while providing sufficient strength to meet a customer's requirements.

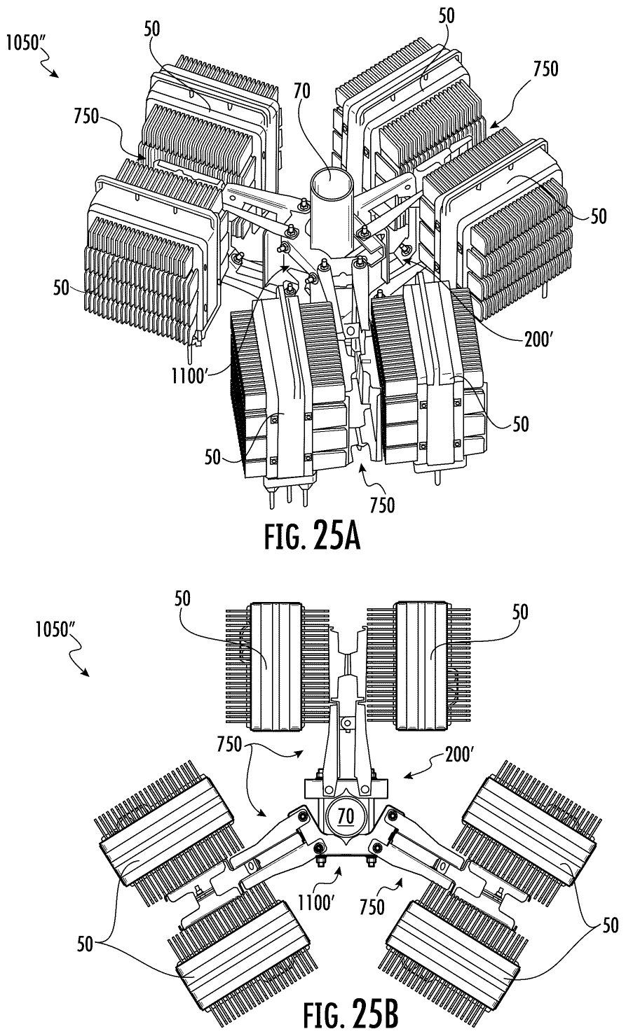

Referring to FIGS. 25A-25B, a mounting assembly 1050″ according to embodiments of the present invention is illustrated. In some embodiments, the mounting assembly 1050′ utilizes the mounting kit 1000″ described above and is configured to secure up to six (6) remote radio units 50 to a mounting structure 70 (e.g., mounting pole). As shown in FIGS. 25A-25B, the mounting brackets 1100′ and clamp assemblies 200′ of the mounting kit 1000″ are secured to the mounting structure 70 (i.e., the mounting structure 70 is clamped between the mounting brackets 1100′ and clamp members 204 of the clamp assemblies 200′). Mounting panels 750 (or similar mounting panels described herein) are secured to opposing ends of the mounting brackets 1100′ and the clamp members 204 via fasteners 250. The remote radio units 50 are secured back-to-back on the mounting panels 750 as described herein.

FIG. 26 compares the mounting assemblies 1050, 1050″ described herein and illustrates the compact design and mounting position relative to the mounting structure 70 with respect to mounting brackets 1100 compared to the mounting brackets 1100 according to embodiments of the present invention.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. The invention is defined by the following claims, with equivalents of the claims to be included therein.

What is claimed is:

1. A mounting assembly for remote radio units, the mounting assembly comprising:
a first clamping assembly and a second clamping assembly, each clamping assembly comprising front and rear clamp members held together by two threaded bolts that are inserted through aligned holes to secure the respective clamping assembly to a mounting structure; and
a first mounting panel and a second mounting panel, an end of each mounting panel secured to one of the clamp members for each clamping assembly such that the mounting panels extend outwardly from the clamping assemblies and parallel to each other, the first and second mounting panels each comprising a section configured to have a remote radio unit mounted thereon in a back-to-back orientation.

2. The mounting assembly according to claim 1, wherein the first and second mounting panels extend outwardly in a first direction that is perpendicular to an axis defined by the mounting structure.

3. The mounting assembly according to claim 1, wherein the first and second mounting panels have mirrored configurations.

4. The mounting assembly according to claim 1, wherein each mounting panel comprises a mounting section and an extension section, the mounting section is configured to have a remote radio unit secured thereto and the extension section is configured to be secured to the clamp assemblies and position the remote radio unit a sufficient distance from the mounting structure.

5. The mounting assembly according to claim 4, wherein each mounting panel comprises a plurality of apertures positioned in the mounting section such that the mounting assembly can accommodate mounting locations for a variety of different types and/or sizes of remote radio units.

6. The mounting assembly according to claim 4, wherein the mounting section of each mounting panel comprises opposing flanged edges having a stabilizing member extending outwardly therefrom, and wherein corresponding stabilizing members from each mounting panel are configured to align with each other to receive a fastener to couple the two mounting panels together.

7. The mounting assembly according to claim 4, wherein the extension section of each mounting panel comprises opposing flanged edges having an end that extends axially outwardly from an outer edge of the extension section and a pair of securing flange members extending outwardly from the outer edge of the extension section, and wherein the opposing flanged edges of the extension section and a respective securing flange member are configured to engage a respective clamp member therebetween to secure the mounting panel to the clamping assemblies.

8. The mounting assembly according to claim 6, wherein each mounting panel includes one or more additional stabilizing members extending outwardly from the extension section, and wherein corresponding additional stabilizing members for each mounting panel are configured to align with each other to receive a fastener.

9. The mounting assembly according to claim 8, wherein the one or more additional stabilizing members reside at an angle relative to the opposing flanged edges of the extension section.

10. The mounting assembly according to claim 1, wherein each mounting panel comprises one or more apertures that are configured to receive a hoisting cable.

11. A mounting assembly for remote radio units, the mounting assembly comprising:
a first clamping assembly and a second clamping assembly, each clamping assembly comprising front and rear clamp members held together by two threaded bolts that are inserted through aligned holes to secure the respective clamping assembly to a mounting structure; and
a first mounting panel and a second mounting panel, an end of each mounting panel secured to one of the clamp members for each clamping assembly such that the mounting panels extend outwardly from the clamping assemblies and parallel to each other, each mounting panel comprising:
a mounting section having a plurality of apertures, the plurality of apertures positioned in the mounting section such that the mounting assembly can accommodate mounting locations for a variety of different types and/or sizes of remote radio units;
an extension section configured to be secured to the clamp assemblies and position the remote radio units a sufficient distance from the mounting structure; and
one or more stabilizing members, wherein corresponding stabilizing members from each mounting panel are configured to align with each other to receive a fastener to couple the two mounting panels together,
wherein the first and second mounting panels are configured to have a respective remote radio unit mounted thereon in a back-to-back orientation.

12. The mounting assembly according to claim 11, wherein the first and second mounting panels extend outwardly in a first direction that is perpendicular to an axis defined by the mounting structure.

13. The mounting assembly according to claim 11, wherein the extension section of each mounting panel comprises opposing flanged edges having an end that extends axially outwardly from an outer edge of the extension section and a pair of securing flange members extending outwardly from the outer edge of the extension section, and wherein the opposing flanged edges of the extension section and a respective securing flange member are configured to engage a respective clamp member therebetween to secure the mounting panel to the clamping assemblies.

14. The mounting assembly according to claim 11, further comprising one or more additional stabilizing members residing at an angle relative to an outer edge of the extension section.

15. A mounting kit for remote radio units, the mounting kit comprising:
a mounting assembly comprising a mounting bracket and a clamp member, the mounting bracket and clamp member held together by two threaded bolts that are inserted through aligned holes to secure the mounting assembly to a mounting structure;
a first pair of mounting panels secured to an end of the mounting bracket, the first pair of mounting panels extending outwardly from the mounting bracket and parallel to each other; and
a second pair of mounting panels secured to an opposing end of the mounting bracket, the second pair of mounting panels extending outwardly from the mounting bracket and parallel to each other,
wherein each mounting panel comprises a section configured to have a remote radio unit mounted thereon in a back-to-back orientation.

16. The mounting kit according to claim 15, wherein the mounting assembly comprises a pair of mounting brackets and a pair of clamp members, the first and second pairs of mounting panels secured to opposing ends of the pair of mounting brackets.

17. The mounting kit according to claim 15, wherein four remote radio units are secured to the mounting panels.

18. The mounting kit according to claim 15, further comprising a third pair of mounting panels secured to the clamp member, the third pair of mounting panels extending outwardly from the clamp member and parallel to each other, wherein each mounting panel of the third pair of mounting panels comprises a section configured to have a remote radio unit mounted thereon in a back-to-back orientation.

19. The mounting kit according to claim 18, wherein the mounting assembly comprises a pair of mounting brackets and a pair of clamp members, the first and second pairs of mounting panels secured to opposing ends of the pair of mounting brackets and the third pair of mounting panels secured to the pair of clamp members.

20. The mounting kit according to claim 18, wherein six remote radio units are secured the mounting panels.
